(19) United States
(12) Patent Application Publication
(10) Pub. No.: US 2025/0294782 A1
(43) Pub. Date: Sep. 18, 2025

(54) SEMICONDUCTOR DEVICE

(71) Applicant: ROHM CO., LTD., Kyoto-shi (JP)

(72) Inventors: Keiji WADA, Kyoto-shi (JP); Koji SAITO, Kyoto-shi (JP)

(21) Appl. No.: 19/075,011

(22) Filed: Mar. 10, 2025

(30) Foreign Application Priority Data
Mar. 18, 2024 (JP) 2024-042544

(51) Int. Cl. H10D 1/47; H01L 23/522; H01L 23/528

(52) U.S. Cl. CPC H10D 1/47; H01L 23/5223; H01L 23/528

(57) ABSTRACT

A semiconductor device includes an insulating layer formed on a semiconductor substrate; and a resistor embedded in the insulating layer; wherein the resistor comprises: a first resistor layer; a first buried electrode electrically connected to one end of the first resistor layer; a first dummy wiring capacitively coupled to the first buried electrode; a second resistor layer disposed adjacent to the first resistor layer; and a second buried electrode electrically connected to one end of the second resistor layer and electrically connected to the first dummy wiring.

### CROSS-REFERENCE TO RELATED APPLICATIONS

This application claims the benefit of priority to Japanese Patent Application No. 2024-042544, filed on Mar. 18, 2024. The entire contents of the above-identified application are hereby incorporated by reference.

### TECHNICAL FIELD

The present disclosure relates to a semiconductor device.

### BACKGROUND

International Publication No. WO 2023/085026 discloses a semiconductor device including a plurality of resistor elements in a chip.

### BRIEF DESCRIPTION OF THE DRAWINGS

FIG. 1 is a plan view of a semiconductor package on which a high voltage detection device is mounted.

FIG. 2 is a circuit diagram of a high voltage detection device.

FIG. 3A is a circuit diagram of a first example of a resistor.

FIG. 3B is a circuit diagram of a second example of the resistor.

FIG. 4 is a circuit diagram of the resistor including a high resistance part.

FIG. 5 is a plan view of the resistor including the high resistance part.

FIG. 6A is a vertical sectional view of the configuration of the resistor shown in FIG. 5 along arrows A-A.

FIG. 6B is a vertical sectional view of the configuration of the resistor shown in FIG. 5 along arrows B-B.

FIG. 6C is a vertical sectional view of the configuration of the resistor shown in FIG. 5 along arrows C-C.

FIG. 7 is a circuit diagram of the resistor including the high resistance part.

FIG. 8 is a plan view of the resistor including the high resistance part.

FIG. 9A is a vertical sectional view of the configuration of the resistor shown in FIG. 8 along arrows A-A.

FIG. 9B is a vertical sectional view of the configuration of the resistor shown in FIG. 8 along arrows B-B.

FIG. 9C is a vertical sectional view of the configuration of the resistor shown in FIG. 8 along arrows C-C.

FIG. 10 is a perspective view in the vicinity of an end portion of a resistor layer.

FIG. 11 is a plan view of the resistor in which dummy wiring is arranged in the vicinity of an input electrode for high voltage.

FIG. 12 is a plan view of an example of a resistor chip.

FIG. 13 is a plan view of a region in the vicinity of the high resistance part of the resistor chip.

FIG. 14 is a plan view of the resistor including the high resistance part in which the arrangement interval of resistor layers is changed.

FIG. 15A is a plan view of a low resistance part for voltage detection.

FIG. 15B is a plan view of a low resistance part for voltage detection.

FIG. 15C is a plan view of a low resistance part for voltage detection.

FIG. 16 is a perspective view in the vicinity of an end portion of the resistor layer.

### DETAILED DESCRIPTION

The various exemplary embodiments will be described in detail with reference to the drawings below.

In the drawings, the same reference numerals will be used for the same or equivalent parts, and redundant explanations will be omitted.

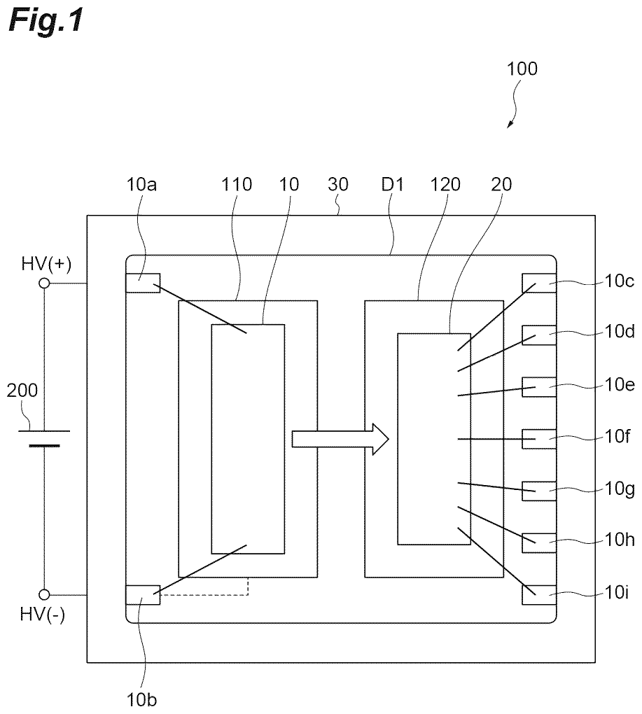

FIG. 1 is a plan view of a semiconductor package 100 on which a high voltage detection device is mounted. In this figure, an upper lid member is omitted.

The semiconductor package 100 includes a case 30 having a recess D1. The case 30 is made of an insulating material such as resin or ceramic. The semiconductor package 100 includes a resistor chip 10 (semiconductor device) disposed on a first die pad 110 in the recess D1, and an amplifier chip 20 (semiconductor device) disposed on a second die pad 120 in the recess D1. The opening of the recess D1 of the semiconductor package 100 is sealed by a lid member (not shown), and the inside of the recess D1 is made into a sealed space. The lid member can be made of an insulating material such as resin; the recess D1 may be filled with a gas, or an insulating material may be filled therein. Appropriate potentials such as ground potential may be applied to the first die pad 110 and the second die pad 120 via a lead frame. It is also possible to set, for instance, a high potential to the first die pad 110, depending on necessity.

An output voltage of the resistor chip 10 is input to the amplifier chip 20. The amplifier chip 20 outputs a voltage corresponding to the detected voltage.

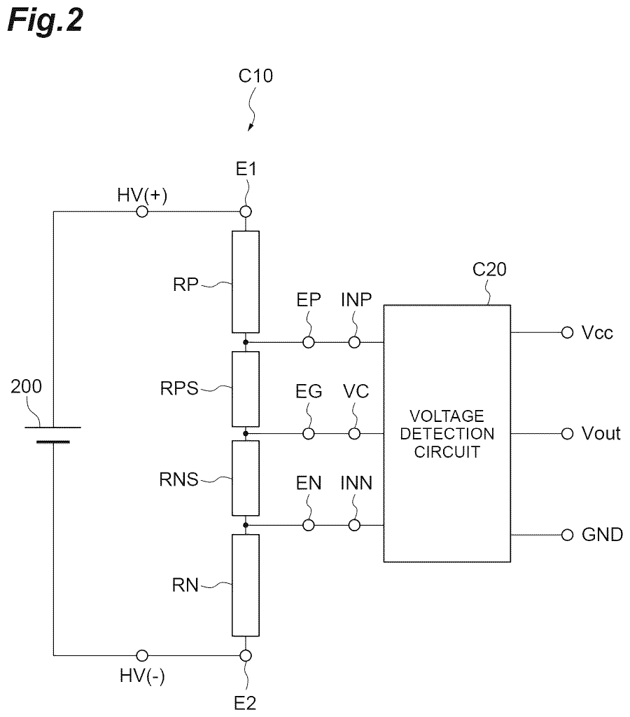

A positive terminal of a battery 200 is electrically connected to a first inner lead 10a, and connected via bonding wires to a first electrode E1 (see FIG. 2) of the resistor chip 10. A negative terminal of the battery 200 is electrically connected to a second inner lead 10b, and is connected to a second electrode E2 (see FIG. 2) of the resistor chip 10 via a bonding wire.

Each terminal of the amplifier chip 20 can be connected via a bonding wire to a third inner lead 10c, a fourth inner lead 10d, a fifth inner lead 10e, a sixth inner lead 10f, a seventh inner lead 10g, an eighth inner lead 10h, and a ninth inner lead 10i.

For example, the power supply voltage Vcc is applied to the third inner lead 10c and is input to the amplifier chip 20. The ground potential GND is applied to the ninth inner lead 10i and is input to the amplifier chip 20. The sixth inner lead 10f can output the output voltage Vout. From the fourth inner lead 10d, a monitor signal corresponding to the potential of a first output electrode EP (see FIG. 2) can be output. From the eighth inner lead 10h, a monitor signal corresponding to the potential of a second output electrode EN (see FIG. 2) can be output. The fifth inner lead 10e and the seventh inner lead 10g may be used for other purposes as necessary.

FIG. 2 is a circuit diagram of a high voltage detection device. The high voltage detection device includes a resistor circuit C10 (voltage divider circuit) and a voltage detection circuit C20. The resistor chip 10 described above includes the resistor circuit C10. The amplifier chip 20 includes the voltage detection circuit C20. A first input terminal HV(+) of the resistor circuit C10 is electrically connected to the positive terminal of the battery 200. A second input terminal HV(−) of the resistor circuit C10 is electrically connected to the negative terminal of the battery 200. The first input terminal HV(+) is electrically connected to a first electrode E1 (electrode pad). The second input terminal HV(−) is electrically connected to a second electrode E2 (electrode pad).

The resistor circuit C10 includes a first high resistance part RP (a first resistor), a first low resistance part RPS, a second low resistance part RNS, and a second high resistance part RN (a second resistor). Between the first electrode E1 and the second electrode E2, the first high resistance part RP, the first low resistance part RPS, the second low resistance part RNS, and the second high resistance part RN are connected in series in this order. The first high resistance part RP and the second high resistance part RN function to reduce the high voltage, and each of them has a relatively large resistance value. The first low resistance part RPS and the second low resistance part RNS function to detect the voltage, and each has a relatively low resistance value as compared to the high resistance parts.

An exemplary value of the resistance of one high resistance part is 500 MΩ, but it may be set to 1 MΩ or more and 1000 MΩ or less. The resistance value of the high resistance part may also be set to 100 MΩ or more and 800 MΩ or less. The resistance value of the high resistance part may also be set to 300 MΩ or more and 600 MΩ or less. The resistance value may be set a resistance value that can provide the capability of voltage detection withstanding high voltage.

The resistance value of one low resistance part (RPS or RNS) is at or below K % of the resistance value of the high resistance part. Exemplary values for K % include 5%, 3%, 1%, 0.5%, 0.3%, 0.1%, 0.05%, or 0.01%, and the resistance of the low resistance part may, for instance, be set to 0.01 MΩ to 10 MΩ.

A connection point between the first high resistance part RP and the first low resistance part RPS is electrically connected to a first output electrode EP (electrode pad). A connection point between the second high resistance part RN and the second low resistance part RNS is electrically connected to a second output electrode EN (electrode pad). A reference electrode EG (electrode pad) is electrically connected between the first low resistance part RPS and the second low resistance part RNS.

Since the resistor circuit C10 is a voltage divider circuit, it is possible to obtain a voltage corresponding to the resistance value between selected two nodes within the resistor circuit C10. The first output electrode EP is electrically connected to a first input terminal INP of the voltage detection circuit C20. The second output electrode EN is electrically connected to a second input terminal INN of the voltage detection circuit C20. The reference electrode EG is electrically connected to a reference terminal VC of the voltage detection circuit C20. The potential of the reference terminal VC can be set to, for example, the ground potential. The voltage detection circuit C20 can output an output voltage Vout. The output voltage Vout can be the total of the difference between the first input terminal INP and the reference terminal VC and the difference between the second input terminal INN and the reference terminal VC. The voltage detection circuit C20 may be provided with a source follower (amplifier) to amplify the voltage input from the input terminals, and may include a differential amplifier circuit to obtain the sum of the magnitudes of the input voltages. The voltage detection circuit C20 includes an input terminal for a power supply voltage Vcc for operating its internal circuit, and an input terminal for setting the ground potential GND.

The resistor circuit C10 can include dummy resistors.

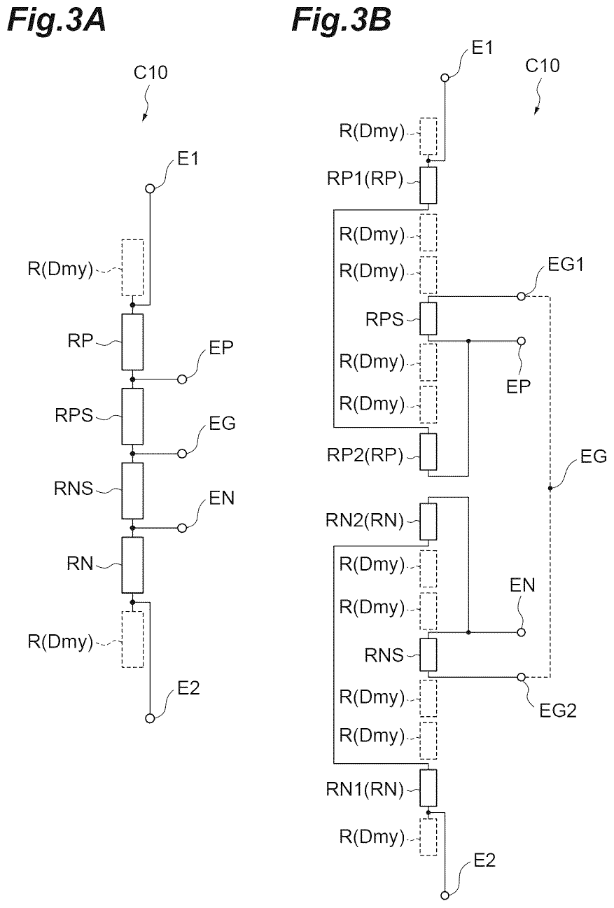

FIG. 3A is a circuit diagram of a first example of a resistor, and FIG. 3B is a circuit diagram of a second example of a resistor.

In the resistor circuit C10 of FIG. 3A, one end of a dummy resistor R(Dmy) is electrically connected to the input side of the first high resistance part RP. A dummy resistor R(Dmy) is electrically connected to the input side of the second high resistance part RN. The dummy resistor need not necessarily be electrically connected to the resistor. For example, a resistor at each end of a resistor chip may have slightly different resistance characteristics from those near the center part. By handling such a resistor as a dummy resistor, detection accuracy may be improved.

The resistor circuit C10 of FIG. 3B is a modified configuration of the first example. In this example, the first high resistance part RP is composed of a high resistance part RP1 and a high resistance part RP2 connected in series, and the second high resistance part RN is composed of a high resistance part RN1 and a high resistance part RN2 connected in series. Moreover, the reference electrode EG is split into a first reference electrode EG1 and a second reference electrode EG2, and these electrodes may be electrically connected on the voltage detection circuit side. Furthermore, compared with the circuit of the first example, one or more dummy resistors R(Dmy) are also provided between each of the resistor parts.

A dummy resistor is a resistor that does not conduct current under normal conditions, and is provided for maintaining electrical equivalence in the resistor circuit C10, for maintaining electrical stability, or for reducing error factors in resistor formation during manufacturing processes. The circuit configuration of the high voltage detection device is not limited to the examples provided and may be modified in terms of the shape and arrangement of the resistors as long as the basic voltage detection function can be achieved.

The high voltage detection device described above can be housed within one semiconductor package as explained. The functions of each circuit can also be split between the resistor chip and the amplifier chip and mounted within the package. It is likewise possible to move some circuit components to one chip or to another, or to integrate them together in a single chip.

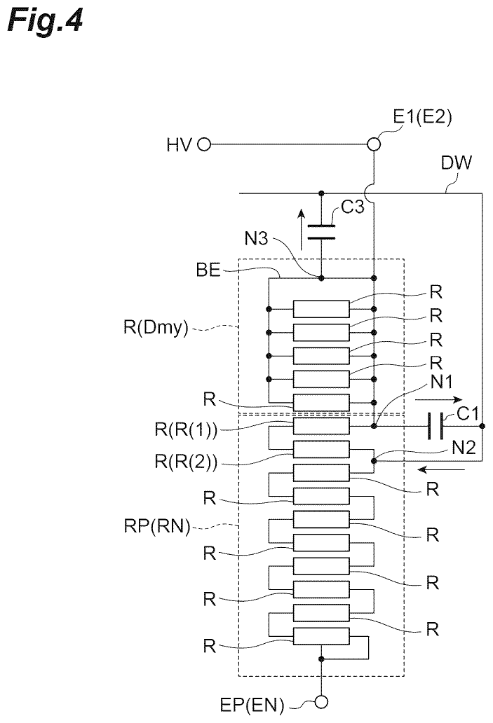

FIG. 4 is a circuit diagram of a resistor including a high resistance part.

The input terminal for high voltage (HV) is connected to the first electrode E1 (or second electrode E2). The first electrode E1 is electrically connected to the first high resistance part RP. The second electrode E2 is electrically connected to the second high resistance part RN. The first high resistance part RP (or the second high resistance part RN) includes a plurality of resistors R connected in series. For the first high resistance part RP (or second high resistance part RN), a first node N1 is defined as the node that first receives a high voltage (high potential). Within the first high resistance part RP (or second high resistance part RN), a second node N2 of the resistor R adjacent to the resistor R connected to the first node N1 is located next to the first node N1.

A dummy resistor R(Dmy) (an extending region) is electrically connected to an end of the first high resistance part RP (or second high resistance part RN). The dummy resistor R(Dmy) includes one or more resistors R. Each resistor R forms a resistor layer, which may take a linear shape in plan view; in other words, it can be called a linear resistor or a straight-shaped resistor. In this example of the dummy resistor R(Dmy), both ends of each resistor R are short-circuited, and the plurality of resistors R are connected in parallel. In the present example, a buried electrode BE (buried wiring) including a third node N3 short-circuits both ends of each resistor R in the dummy resistor R(Dmy), although other wiring may be used for the short-circuit.

This wiring for short-circuiting, i.e., the buried electrode BE(buried wiring), may be disposed directly beneath the dummy resistor R(Dmy). The buried electrode BE for short-circuiting is capacitively coupled to the dummy wiring DW that is disposed in its vicinity, constituting a parasitic capacitor C3. The dummy wiring DW does not ordinarily conduct current but can pass AC if a surge voltage or the like is applied. It is also possible to extend the dummy wiring DW up to the vicinity of the input electrode for high voltage (the first electrode E1 or the second electrode E2).

If a large voltage relative to the ground potential is applied to the first electrode E1 (or second electrode E2), that voltage is transmitted to the first node N1. Under steady-state conditions, the magnitude of the potential at the first node N1 drops via one or more resistors R connected in series, and the potential after this voltage drop appears at the second node N2. If the magnitude of the potential at the first node N1 quickly rises, the second node N2 cannot immediately follow that change, so there arises a large potential difference between the first node N1 and the second node N2.

For example, suppose the gap between a first resistor R (R(1)) having one end at the first node N1 and a second resistor R (R(2)) having the second node N2 is 1 μm. In this case, if a voltage (e.g., 4000V) exceeding the withstand voltage of the gap (e.g., 500V) is applied between the first node N1 and the second node N2, it may result in a breakdown.

In this example, the second node N2 is connected to the dummy wiring DW. The dummy wiring DW constitutes a parasitic capacitor C1 with the buried electrode that includes the first node N1. Therefore, the dummy wiring DW is capacitively coupled to the first node N1 via the capacitor C1 and is also capacitively coupled to the third node N3 via the capacitor C3.

The potential at the first node N1 is the same as the potential at the third node N3. If the magnitude of the potential at the third node N3 (and the first node N1) rapidly increases, current flows from the buried electrode BE, through the third capacitor C3, into the dummy wiring DW, and current also flows through the first capacitor C1 into the dummy wiring DW, thereby raising the potential at the second node N2. In other words, the potential difference between the first node N1 and the second node N2 can be decreased, mitigating failures near the node due to rapid voltage changes.

For example, it is preferable that the combined capacitance of capacitors C1 and C3 be at least 1 fF or more, desirably 10 fF or more. If the combined capacitance is within this range, it is considered possible to adequately suppress rapid voltage changes.

Additionally, if the potential at the second node N2 increases rapidly, a potential difference may occur between N2 and the node of the adjacent resistor R on the lower potential side, which could also lead to a breakdown due to this potential difference. Therefore, it is generally preferable to connect dummy wiring to one end of each resistor R.

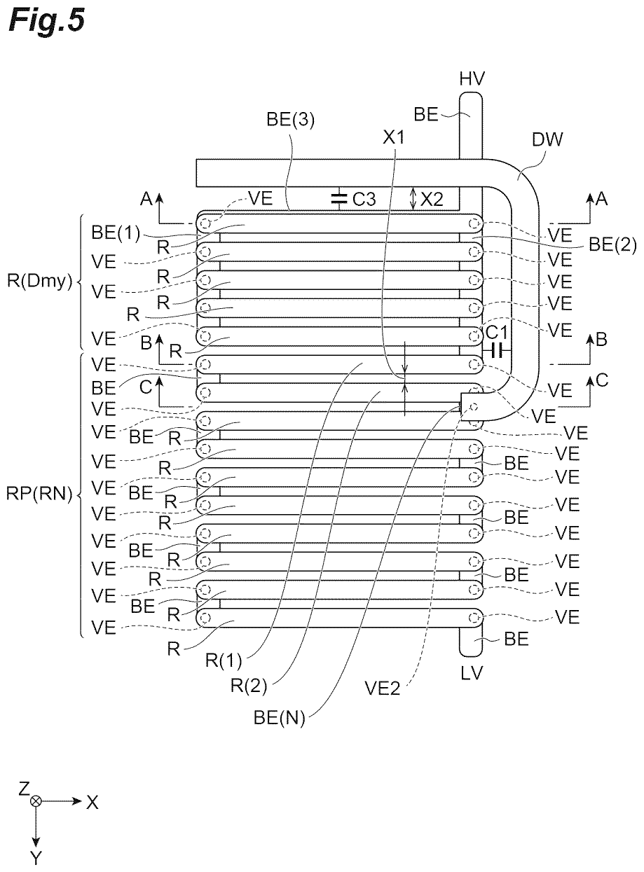

FIG. 5 is a plan view of a resistor including a high resistance part shown in FIG. 4. Note that the resistor, the buried electrode, and the dummy wiring are embedded in the insulating layer, but for clarity in explanation, the insulating layer is not shown.

Each resistor R extends along the X-axis direction, and a plurality of these resistors R are arranged along the Y-axis direction. The Z-axis is the depth direction of the chip, and is perpendicular to both the X-axis and the Y-axis. The underside of each end of each resistor R is physically and electrically connected to a via electrode VE, and the via electrode VE is physically and electrically connected to the buried electrode BE. The physical connection of the conductive elements involves electrical connection as well. Therefore, in the description, when the connection state is clear, the term “connection” may simply be used.

In the dummy resistor R(Dmy), the buried electrode BE includes a first connection region BE(1) that connects one end of the plurality of resistors R, a second connection region BE(2) that connects the other end of the plurality of resistors R, and a third connection region BE(3) that connects these connection regions. The third connection region BE(3) forms one electrode of the third capacitor C3.

In the first high resistance part RP (or the second high resistance part RN), the buried electrode BE connects one side end of the nth resistor R and one side end of the (n+1)-th resistor R along the Y-axis direction, and connects the other side end of the (n+1)-th resistor R and the other side end of the (n+2)-th resistor R (where n is a natural number).

It is also possible to reverse the vertical positional relationships of the via electrode VE and the buried electrode BE with respect to each of the resistors R. In such a case, each resistor R is located in a layer below the via electrode VE and the buried electrode BE.

The buried electrode BE connected to the input electrode that receives the high voltage (HV) is connected, through the buried electrode BE(the second connection region BE(2)) beneath one end of the dummy resistor R(Dmy), via a via electrode VE, to the input-side end of the first resistor R in the first high resistance part RP. The one end of the next second resistor R is connected, via a via electrode VE, to the buried electrode BE(N). The buried electrode BE(N), like other buried electrodes BE, connects the one end of adjacent resistors R via the via electrode VE. The buried electrode BE(N) is connected, via a second via electrode VE2, to dummy wiring DW above it.

The plurality of resistors R in the high resistance part are connected in series between the electrode that receives the high voltage (HV) and the output electrode at low voltage (LV).

In plan view, the region containing the dummy resistor R(Dmy) is an extending region in the longitudinal direction (the Y-axis direction) of the resistor as viewed from the high resistance part. The shortest distance X1 between the first buried electrode (the second connection region BE(2)) and the second buried electrode (the buried electrode BE(N)) that are included in this extending region, and the shortest distance X2 between the first buried electrode (the third connection region BE(3)) included in the extending region and the dummy wiring DW, satisfy a relationship X1≤X2. In the third capacitor C3 that gives X2, the electric field intensity tends to be smaller, increasing the tolerance for voltage.

As described, the above resistor chip includes an insulating layer formed on a semiconductor substrate, and a resistor embedded within the insulating layer. The resistor includes: a first resistor layer (the first resistor R(1) at the high potential side in the high resistance part); a first buried electrode (the second connection region BE(2)) electrically connected to one end of the first resistor layer; a first dummy wiring (DW) that is capacitively coupled to the first buried electrode via the third capacitor C3 (and the first capacitor C1); a second resistor layer (the second resistor R(2)) disposed adjacent to the first resistor layer (resistor R(1)); and a second buried electrode (BE(N)) electrically connected to one end of the second resistor layer (resistor R(2)) and electrically connected to the first dummy wiring (DW).

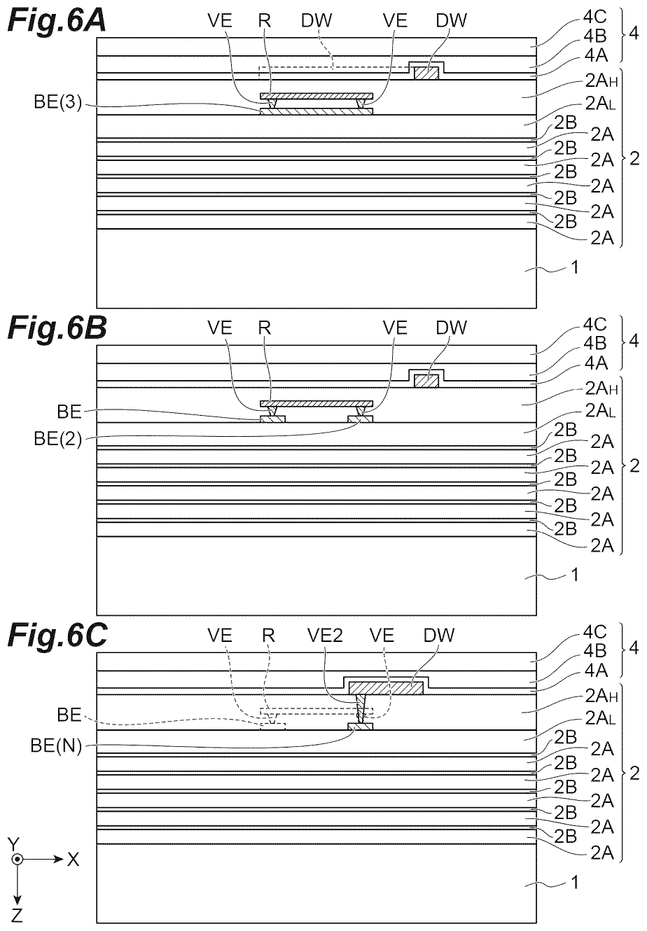

FIG. 6A is a vertical sectional view of the configuration of the resistor shown in FIG. 5 along arrows A-A, FIG. 6B is a vertical sectional view of the configuration of the resistor shown in FIG. 5 along arrows B-B, and FIG. 6C is a vertical sectional view of the configuration of the resistor shown in FIG. 5 along arrows C-C.

As illustrated in FIGS. 6A to 6C, the resistor chip includes a semiconductor substrate 1, an insulating layer 2 provided on the semiconductor substrate 1, and a protective film 4 provided on the insulating layer 2.

The insulating layer 2 includes multiple stacked dielectric layers (a first dielectric layer 2A and a second dielectric layer 2B). At least one of these multiple dielectric layers (the first dielectric layer 2A) contains silicon oxide. At least one of these multiple dielectric layers (the second dielectric layer 2B) contains silicon nitride. In this example, the first dielectric layer 2A and the second dielectric layer 2B are alternately stacked. The silicon oxide in this example is SiO₂; its elemental ratio may be changed as needed, and other elements may be contained. The silicon nitride in this example is Si₃N₄; its elemental ratio may be changed as needed, and other elements may be contained. The thickness of the insulating layer 2 may be, for example, between 5 μm and 50 μm.

The insulating layer 2 includes a lower dielectric layer 2A_{L} formed on the top of the second dielectric layer 2B at the highest position, and an upper dielectric layer 2A_{H} formed on the lower dielectric layer 2A_{L}. The exemplary materials of the lower dielectric layer 2A_{L} and the upper dielectric layer 2A_{H} are the same as the material of the first dielectric layer 2A.

The protective film 4 includes a first protective film 4A, a second protective film 4B, and a third protective film 4C, sequentially stacked on top of the insulating layer 2. As the material of the first protective film 4A, an inorganic insulating material such as silicon oxide or silicon nitride can be used, for example, SiO₂. The second protective film 4B is formed on the first protective film 4A. The second protective film 4B is also made of an inorganic insulating material such as silicon oxide or silicon nitride; it may be the same material as the first protective film 4A or a different one, for example, silicon nitride. The third protective film 4C is made of a resin (insulating material) such as polyimide.

The buried electrodes BE(including BE(1) to BE(3), BE(N)) are formed on the lower dielectric layer 2A_{L} and located within the upper dielectric layer 2A_{H}. The upper dielectric layer 2A_{H} can include multiple dielectric layers (insulating layers), and resistors R(resistor layers) are formed on a particular dielectric layer within the upper dielectric layer 2A_{H}. The buried electrode BE and the resistor R are connected by the via electrode VE. Moreover, as shown in FIG. 6C, the lower surface of the dummy wiring DW is connected to the buried electrodes BE(N) below via the second via electrode VE2 passing through the upper dielectric layer 2A_{H}.

Next, an example is described in which a plurality of dummy wirings are electrically connected to one end of each resistor R.

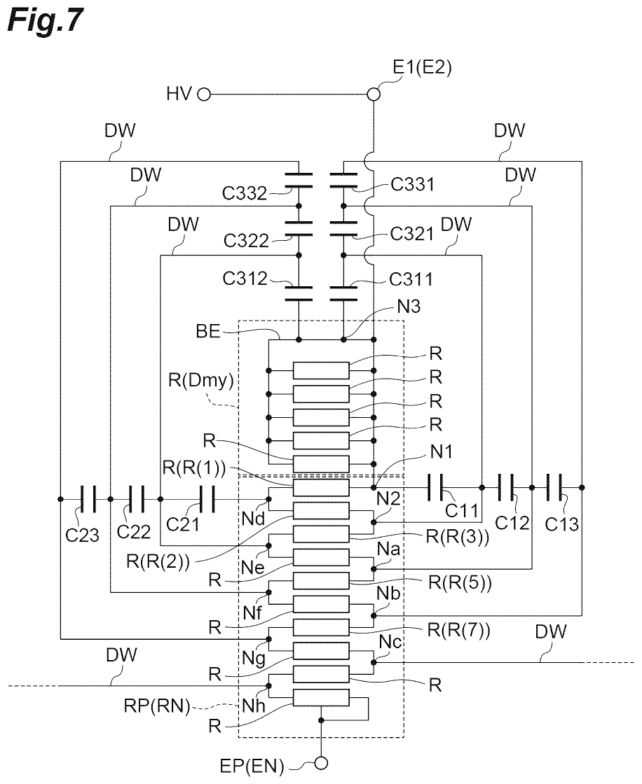

FIG. 7 is a circuit diagram of a resistor including a high resistance part.

A high voltage (HV) input terminal is connected to the first electrode E1 (or second electrode E2). The first electrode E1 is electrically connected to the first high resistance part RP. The second electrode E2 is electrically connected to the second high resistance part RN. The first high resistance part RP (or second high resistance part RN) includes a plurality of resistors R connected in series. In the first high resistance part RP (or second high resistance part RN), the first node N₁ is defined as the node that first receives the high voltage (high potential). Within the first high resistance part RP (or second high resistance part RN), the second node N₂ of the resistor R adjacent to the resistor R connected to the first node N1 is adjacent to the first node N₁.

A dummy resistor R(Dmy) is electrically connected to an end of the first high resistance part RP (or second high resistance part RN). The dummy resistor R(Dmy) includes one or more resistors R. Each resistor R is a resistive layer, and a specific example of its planar shape is a linearly extended straight shape. In the present example of the dummy resistor R(Dmy), both ends of each resistor R are short-circuited, and the plurality of resistors R are connected in parallel. In this example, a buried wiring BE that includes a third node N₃ short-circuits the two ends of each resistor R in the dummy resistor R(Dmy), but a short-circuit using other wiring is also possible.

The buried wiring BE for short-circuiting can be arranged directly beneath the dummy resistor R(Dmy). The buried wiring BE for short-circuiting is capacitively coupled to two dummy wirings DW arranged in its vicinity, each of which constitutes a parasitic third capacitor (C311, C312). The dummy wiring DW is a wiring that normally does not carry current but can function as a bypass wiring to carry AC if a surge voltage or the like is applied. It is also possible to extend the dummy wiring DW up to the vicinity of the high voltage input electrode (the first electrode E1 or the second electrode E2).

When a large voltage is applied to the first electrode E1 (or second electrode E2) with respect to ground potential, that voltage is transmitted to the first node N1. Under steady-state conditions, the potential at the first node N1 is lowered through one or more resistors R connected in series, and the lowered potential appears at the second node N2. If the potential at the first node N1 rapidly increases, the potential at the second node N2 cannot immediately follow the change. Consequently, as explained in the earlier example, a large potential difference arises between the first node N1 and the second node N2, and failure may occur.

The second node N2 is connected to the dummy wiring DW. The dummy wiring DW forms a parasitic first capacitor (C11) with the buried electrode that includes the first node N1. Therefore, the dummy wiring DW is capacitively coupled to the first node N1 via the capacitor (C11) and is capacitively coupled to the third node N3 via the capacitor (C311).

The potential at the first node N1 is the same as at the third node N3. If the magnitude of the potential at the third node N3 (and the first node N1) rapidly increases, current flows from the buried electrode BE through the third capacitor (C311) to the dummy wiring DW, and current also flows through the first capacitor (C11) to the dummy wiring DW, thereby raising the potential at the second node N2. Namely, the potential difference between the first node N1 and the second node N2 is reduced, thus mitigating failure near the node due to rapid voltage changes.

If the potential at the second node N2 sharply increases, there is a tendency for a potential difference to occur with respect to the node of the adjacent resistor R.

Accordingly, in the present example, dummy wiring DW is also connected to a node Na adjacent to the second node N2, and together with the dummy wiring DW disposed more inward, forms parasitic capacitors (C12, C321). These capacitors (C12, C321) are connected to the first capacitor (C11) and the third capacitor (C311), and consequently, are connected to the buried electrode BE in the dummy resistor.

Likewise, dummy wiring DW is connected to a node Nb adjacent to the node Na, and together with the dummy wiring DW disposed more inward, forms parasitic capacitor (C13) and forms the capacitor (C331). These capacitors (C13, C331) are connected to the capacitors (C12, C11) and capacitors (C321, C311), and consequently, are coupled to the buried electrode BE in the dummy resistor.

On the opposite side from capacitors (C11 to C13, C311 to C331), multiple dummy wiring DW is arranged so that parasitic capacitors (C21 to C23, C312 to C332) are formed. This circuit arrangement improves equivalency while also mitigating the rapid potential rise at the end opposite the first node N1 in each resistor R.

Specifically, on the side opposite the first node N1 of the first resistor R(1) in the high resistance part, there is a node Nd, and a parasitic capacitor (C21) formed by dummy wiring DW is capacitively coupled there. This dummy wiring DW is connected to a node Ne on the side opposite the second node N2 of the third resistor R(3) in the high resistance part. Together with the buried electrode BE in the dummy resistor, the dummy wiring DW connected to the node Ne forms the parasitic capacitors (C21, C312). The dummy wiring DW connected to node Ne, together with the embedded electrode BE in the dummy resistor, forms parasitic capacitors (C21) and (C312).

On the side opposite the node Na of the fifth resistor R(5) in the high resistance part, there is a node Nf, and the dummy wiring DW connected to the node Nf forms parasitic capacitors (C22) and (C322) along with the adjacent dummy wiring DW.

On the side opposite the node Nb of the seventh resistor R(7) in the high resistance part, there is a node Ng, and the dummy wiring DW connected to the node Ng forms parasitic capacitors (C23) and (C332) along with the inner adjacent dummy wiring DW.

Dummy wirings DW are connected to the other nodes Nc and Nh located at both ends of the resistor R, and these dummy wirings DW are capacitively coupled with adjacent dummy wirings DW. The number of dummy wires is given by way of example, and for instance, the number of dummy wirings on one side of a resistor R can be four or more, six or more, eight or more, or ten or more.

The combined capacitance of the exemplary capacitors (C11, C311) can be set to the same range described for the combined capacitance of capacitors (C1, C3) above. Thus, it is considered possible to sufficiently suppress rapid voltage changes. Likewise, the combined capacitances of (C12, C321), (C13, C331), (C21, C312), (C22, C322), and (C23, C332) can also be set within the same range or other ranges, as needed.

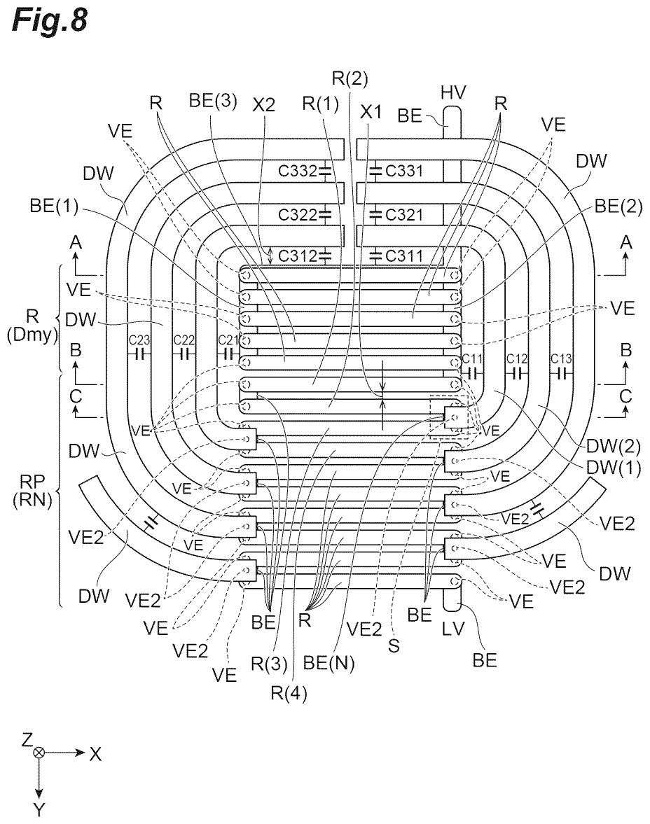

FIG. 8 is a plan view of a resistor including a high resistance part shown in FIG. 7. In reality, the resistor, the buried electrode, and the dummy wiring are embedded in the insulating layer, but for clarity in explanation, the insulating layer is not shown.

Each resistor R extends along the X-axis direction, and a plurality of resistors R are arranged along the Y-axis direction. The underside of both ends of each resistor R is physically and electrically connected to a via electrode VE, and the via electrode VE is physically and electrically connected to a buried electrode BE.

In the dummy resistor R(Dmy), the buried electrode BE includes a first connection region BE(1) that connects one side end of the plurality of resistors R, a second connection region BE(2) that connects the other side end of the plurality of resistors R, and a third connection region BE(3) that connects these connection regions. The third connection region BE(3) constitutes one electrode of the third capacitors (C311, C312).

In the first high resistance part RP (or second high resistance part RN), the buried electrode BE connects one side end of the nth resistor R and one side end of the (n+1)-th resistor R along the Y-axis direction, and connects the other side end of the (n+1)-th resistor R and the other side end of the (n+2)-th resistor R, where n is a natural number.

It is also possible to invert the vertical relationships of the via electrode VE and the buried electrode BE with respect to each resistor R. In such a case, the resistor R is below the via electrode VE and the buried electrode BE.

The buried electrode BE connected to the electrode that receives a high voltage (HV) is connected, via the buried electrode BE(the second connection region BE(2)) beneath one end of the dummy resistor R(Dmy), via a via electrode VE, to the input-side end of the first resistor R(1) of the high resistance part.

One end of the next second resistor R(2) is connected, via a via electrode VE, to the buried electrode BE(N). Like other buried electrodes BE, the buried electrode BE(N) connects the end of neighboring resistors R via a via electrode VE. The buried electrode BE(N) is connected, through a second via electrode VE2 (located within the region S), to the dummy wiring DW above it.

For each resistor side end of the plurality of dummy wirings DW, there is a buried electrode BE located directly beneath, and each dummy wiring DW is connected to its underlying buried wiring BE via the second via electrode VE2.

The plurality of resistors R in the high resistance part are in a series connection between the input-side electrode that receives the high voltage (HV) and the output electrode at a low voltage (LV).

As described above, the resistor chip includes an insulating layer formed on the semiconductor substrate, and a resistor embedded in the insulating layer. The resistor includes: a first resistor layer (the first resistor R(1) at the high potential side in the high resistance part); a first buried electrode (the second connection region BE(2)) electrically connected to one end of the first resistor layer; a first dummy wiring (DW(1)) that is capacitively coupled to the first buried electrode via the capacitors (C311, C11); a second resistor layer (the second resistor R(2) at the second-highest potential side in the high resistance part) disposed adjacent to the first resistor layer (resistor R(1)); and a second buried electrode (BE(N)) electrically connected to one end of the second resistor layer (resistor R(2)) and electrically connected to the first dummy wiring (DW(1)).

Furthermore, the resistor includes a resistor layer (resistor R(3)), a buried electrode BE(N) electrically connected to one end of the resistor layer (resistor R(3)), a first dummy wiring (DW(1)) electrically connected to the buried electrode BE(N), a second dummy wiring (DW(2)) that is capacitively coupled to the first dummy wiring (DW(1)) via capacitors (C321, C12), a (second) buried electrode BE electrically connected to the second dummy wiring (DW(2)), and a resistor layer (resistor R(4)) disposed adjacent to resistor R(3) and electrically connected to the (second) buried electrode BE.

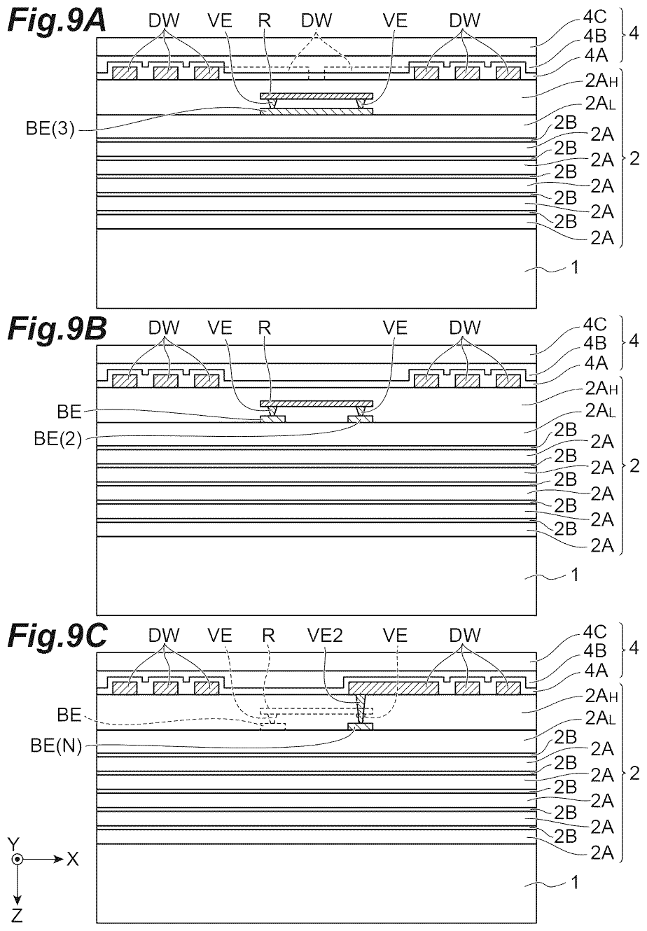

FIG. 9A is a vertical sectional view of the configuration of the resistor shown in FIG. 8 along arrows A-A, FIG. 9B is a vertical sectional view of the configuration of the resistor shown in FIG. 8 along arrows B-B, and FIG. 9C is a vertical sectional view of the configuration of the resistor shown in FIG. 8 along arrows C-C.

As illustrated in FIGS. 9A to 9C, the resistor chip includes the semiconductor substrate 1, the insulating layer 2 formed on the semiconductor substrate 1, and the protective film 4 formed on the insulating layer 2.

The structures of the insulating layer 2 and the protective film 4 are the same as those shown in FIGS. 6A to 6C.

The buried electrodes BE(including BE(1) to BE(3), BE(N)) are formed on the lower dielectric layer 2A_{L} and located within the upper dielectric layer 2A_{H}. The upper dielectric layer 2A_{H} can include a plurality of dielectric layers (insulating layers). The resistor R(resistor layer) is formed on a particular dielectric layer in the upper dielectric layer 2A_{H}. The buried electrode BE and the resistor R are connected by the via electrode VE. Moreover, as illustrated in FIG. 6C, the lower surface of the dummy wiring DW is connected to the lower buried electrode BE(N) via the second via electrode VE2 that passes through the upper dielectric layer 2A_{H}. Each dummy wiring DW is adjacent along the X-axis direction, with the first protective film 4A interposed between them. By changing the dielectric constant of the first protective film 4A, it is also possible to change the dummy wiring inter-wire capacitance.

The capacitance between adjacent dummy wirings depends on the dimension of their gap, the area of their facing side surfaces, and the dielectric constant of the dielectric therebetween. The gap between dummy wirings DW can be configured to meet the above exemplary combined capacitance range.

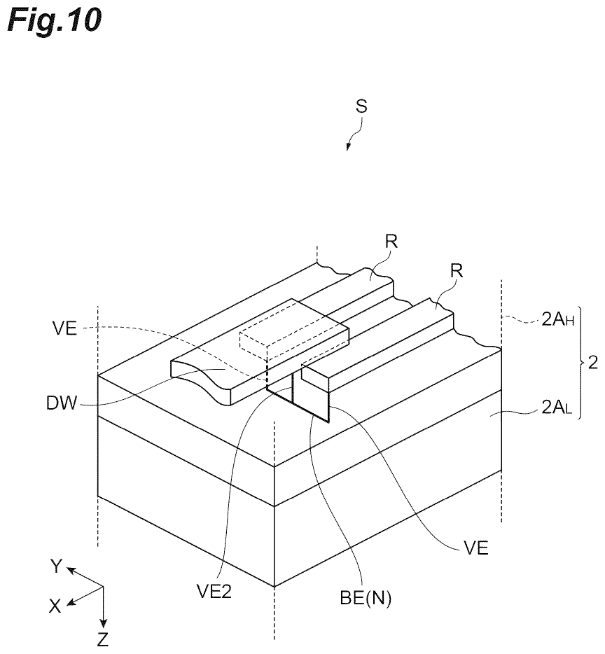

FIG. 10 is a perspective view illustrating an example in the vicinity of an end portion of a resistor layer.

The connection structure between the second via electrode VE2 and the buried wiring BE is the same at all positions but is shown exemplarily for the second via electrode VE2 and the buried wiring BE(N) within region S of FIG. 8.

A pair of resistors R is arranged adjacently. Each resistor R is connected on its underside, via the via electrode VE, to the top surface of the buried wiring BE(N). The top surface of the buried wiring BE(N) is connected, via the second via electrode VE2, to the lower surface of the dummy wiring DW.

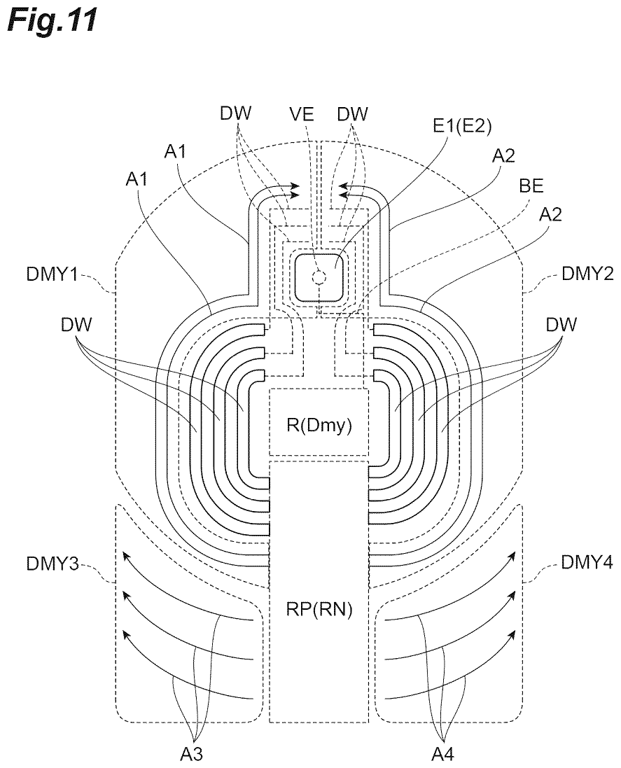

FIG. 11 is a plan view of a resistor in which dummy wiring is arranged in the vicinity of a high-voltage input electrode.

If multiple dummy wirings DW extend from the first high resistance part RP (or the second high resistance part RN) as described above, it is also possible to extend the multiple dummy wirings DW to the vicinity of the first electrode E1 (or the second electrode E2) and arrange them so as to surround the first electrode E1 (or the second electrode E2).

In a first dummy wiring region DMY1 that includes a group of dummy wirings connected to one end side of each resistor, it is possible to arrange multiple dummy wirings on the further outward side of a dummy wiring DW located on the outside the figure, along the direction of the first arrow A1. The dummy wirings of the first dummy wiring region DMY1 extend up to the position on the side opposite the first high resistance part RP (or the second high resistance part RN) of the first electrode E1 (or the second electrode E2).

In a second dummy wiring region DMY2, which includes a group of dummy wirings connected to the other side of each resistor, it is possible to arrange multiple dummy wirings in the direction of the second arrow A2 on the further outward side from a dummy wiring DW located on the outside of the figure. The dummy wirings in the second dummy wiring region DMY2 extend up to the position on the side opposite the first high resistance part RP (or the second high resistance part RN) of the first electrode E1 (or the second electrode E2).

The group of dummy wirings in the first dummy wiring region DMY1 and the group of dummy wirings in the second dummy wiring region DMY2 face each other with a gap in between at positions on the side opposite the first high resistance part RP (or the second high resistance part RN) of the first electrode E1 (or the second electrode E2).

Among the group of dummy wirings connected to one end side of each resistor, which are located on the low voltage side, a third dummy wiring region DMY3 is provided, where multiple dummy wirings can be arranged in the direction of the third arrow A3. The third dummy wiring region DMY3 is adjacent to the first dummy wiring region DMY1, but the dummy wirings in this region do not extend up to the position of the first electrode E1 (or second electrode E2).

Among the group of dummy wirings connected to one end side of each resistor, which are located on the low voltage side, a fourth dummy wiring region DMY4 is provided, where multiple dummy wirings can be arranged along the direction of a fourth arrow A4. The fourth dummy wiring region DMY4 is adjacent to the second dummy wiring region DMY2, but the dummy wirings in this region do not reach the position of the first electrode E1 (or second electrode E2).

Because a large-magnitude potential is applied to the first electrode E1 (or second electrode E2), making the distribution of the electric field around it vary more gently results in higher voltage tolerance. In this structure, some of the dummy wiring extends to a position surrounding the first electrode E1 (or second electrode E2), so that from the high voltage side to the low voltage side, the potential is gradually decreased around the electrode. Hence, the withstand voltage of the resistor chip can be improved. Further, the third dummy wiring region DMY3 and the fourth dummy wiring region DMY4 arranged on the low voltage side can optionally mitigate changes in electric field intensity.

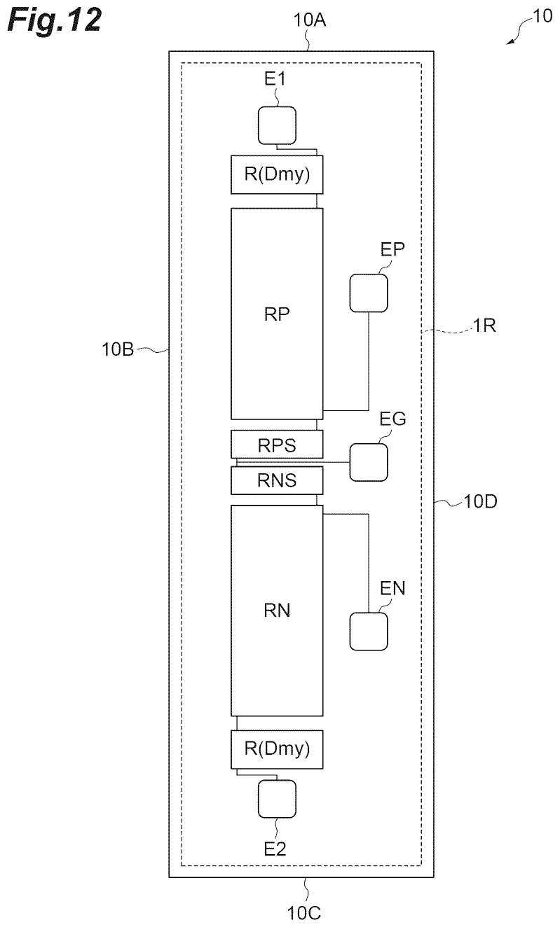

FIG. 12 is a plan view of an example of a resistor chip.

This resistor chip corresponds to the circuit diagram in FIG. 3A. The resistor chip 10 is formed by creating an insulating layer on a semiconductor substrate and embedding resistors in the insulating layer. The plan shape of the resistor chip 10 is rectangular, having a first side 10A, a second side 10B, a third side 10C, and a fourth side 10D. It is possible to embed an annular conductor 1R in the insulating layer along these sides. The annular conductor 1R may be formed from a ring of metal material such as copper; if necessary, one can provide a ring of another material (e.g., CrSi resistor material) that is electrically connected to above or below by a via electrode (e.g., tungsten). The annular body can contribute to the improvement of waterproofing and electrical stability.

In this example, in plan view, the first electrode E1, the dummy resistor R(Dmy), the first high resistance part RP, the first low resistance part RPS, the second low resistance part RNS, the second high resistance part RN, the dummy resistor R(Dmy), and the second electrode E2 are arranged in a line along one direction. The first output electrode EP is electrically connected to a buried electrode disposed between the first high resistance part RP and the first low resistance part RPS. The second output electrode EN is electrically connected to a buried electrode disposed between the second high resistance part RN and the second low resistance part RNS. The reference electrode EG is electrically connected to a buried electrode disposed between the first low resistance part RPS and the second low resistance part RNS.

Another example of a resistor chip may be considered.

For instance, for a resistor chip corresponding to FIG. 3B, several structural variations are possible. Descriptions are provided with reference to the circuit diagram of FIG. 3B and the structure of the resistor chip described above. As with the resistor chip 10 shown in FIG. 12, another example of a resistor chip is formed by creating an insulating layer on a semiconductor substrate and embedding resistors in that insulating layer. The plan shape of the resistor chip 10 is rectangular, with a first side 10A, a second side 10B, a third side 10C, and a fourth side 10D. An annular conductor 1R may be embedded in the insulating layer along these sides. The structure of the annular conductor 1R is as described above.

In another example of the resistor chip, in plan view, the elements shown in FIG. 3B, namely the first electrode E1, the dummy resistor R(Dmy), the high resistance part RP2, the dummy resistor R(Dmy), the dummy resistor R(Dmy), the high resistance part RN2, the dummy resistor R(Dmy), and the second electrode E2, may be arranged in alignment along one direction. Also, in plan view, a high resistance part RP1 and a dummy resistor R(Dmy) are adjacent, in a direction orthogonal to the above direction, to the first electrode E1. The dummy resistor R(Dmy), the high resistance part RP1, the dummy resistor R(Dmy), the first low resistance part RPS, the second low resistance part RNS, the dummy resistor R(Dmy), the high resistance part RN1, and the dummy resistor R(Dmy) are arranged in a line along one direction. The low-voltage side end of the high resistance part RP2 is connected to the first output electrode EP. The low-voltage side end of the high resistance part RN2 is connected to the second output electrode EN.

The low-voltage side end of the first low resistance part RPS may, if necessary, be electrically connected to a first reference electrode EG1 (via an intermediate electrode). The low-voltage side end of the second low resistance part RNS is electrically connected to a second reference electrode EG2. Depending on need, the first and second reference electrodes EG1, EG2 may be short-circuited within the resistor chip or within an external amplifier chip for use as a reference electrode EG.

Although the electrical connections of the circuit elements in this other example of the resistor chip match FIG. 3B, the arrangement of these circuit elements is not limited to the examples described above and may be modified in various ways.

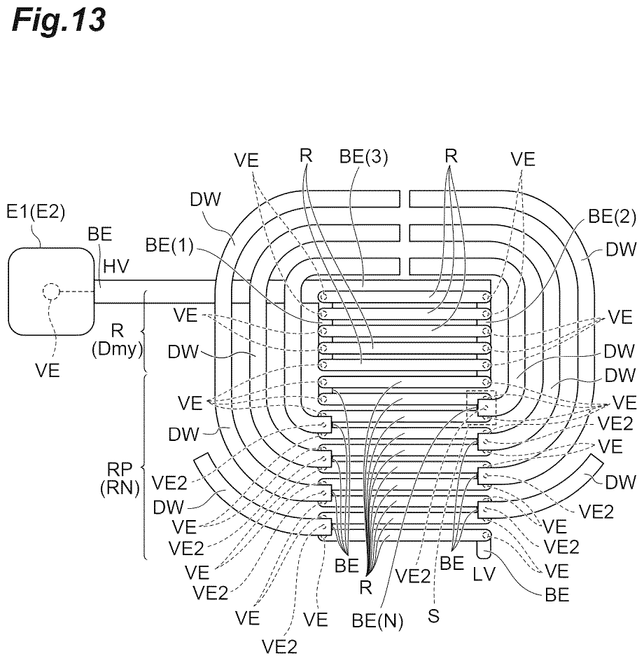

FIG. 13 is a plan view of the region in the vicinity of the high resistance part of the resistor chip.

A dummy resistor R(Dmy) is disposed on the side of the first electrode E1 (or the second electrode E2). The first electrode E1 (or second electrode E2) is disposed at the same depth as the dummy wiring DW. On the high voltage (HV) side of the third connection region BE(3), there is a continuous buried wiring BE, which is electrically connected to the first electrode E1 (or the second electrode E2) via the via electrode VE.

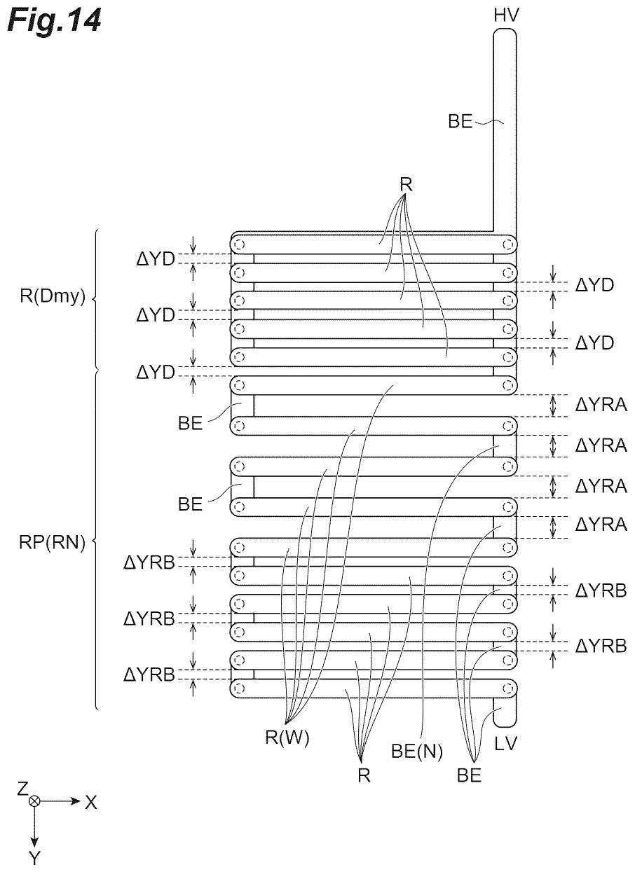

FIG. 14 is a plan view of a resistor including a high resistance part in which the arrangement intervals between resistors R(the resistor layer) are changed.

In the dummy resistor R(Dmy), the gap in the Y-axis direction between adjacent resistors R is ΔYD. In plan view, in the first high resistance part RP (or the second high resistance part RN), the gap in the Y-axis direction between adjacent resistors R has a first gap ΔYRA (the shortest distance between resistors R(W)) and a second gap ΔYRB (the shortest distance between resistors R). The group (first region) of resistors R(W) that produces the first gap ΔYRA is placed at a position closer to the dummy resistor R(Dmy) than the group (second region) of resistors R that produces the second gap ΔYRB. The first gap ΔYRA along the Y-axis direction is larger than the second gap ΔYRB, satisfying the relationship ΔYRB<ΔYRA. The gap ΔYD of the dummy resistor can be set equal to the second gap ΔYRB.

The relationship ΔYRB<ΔYRA allows the electric field strength between resistors R(W) having a wide interval to be lowered, enabling an increase in withstand voltage even if the same potential difference arises.

Each buried electrode BE can be electrically connected to the dummy wiring via the second via electrode as described above. Even if such dummy wiring connections are not made, the effect of increased withstand voltage can still be achieved; however, when dummy wiring is connected, the withstand voltage increases synergistically, further preventing the destruction of the resistor chip.

The configuration of the low resistance part can vary in many ways. Some examples are illustrated below.

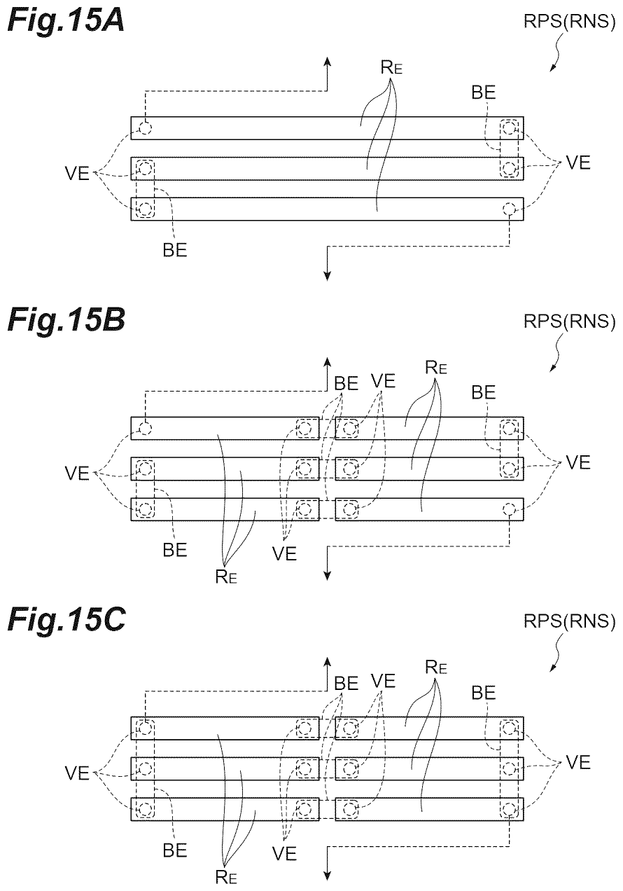

FIG. 15A, FIG. 15B, and FIG. 15C are plan views of respective low resistance parts for voltage detection.

The first low resistance part RPS (or the second low resistance part RNS) includes a plurality of straight-shaped resistors R_{E} that extend linearly. Beneath the ends of each resistor R_{E}, via electrodes VE are arranged, and the via electrodes VE are physically and electrically connected to buried electrodes BE located below. The number of straight-shaped resistors can be three or more or less than three.

In the example shown in FIG. 15A, three straight-shaped resistors R_{E} are illustrated. In the top row in the figure, one end of the first straight-shaped resistor R_{E} is connected, via a via electrode VE and a buried electrode BE, to one end of the second straight-shaped resistor R_{E} in the second row. The other end of the second straight-shaped resistor R_{E} in the second row is connected, via a via electrode VE and a buried electrode BE, to the other end of the third straight-shaped resistor R_{E} in the third row.

In the example shown in FIG. 15B, each straight-shaped resistor in FIG. 15A is split into two in each row, so that multiple straight-shaped resistors R_{E} are disposed per row. Therefore, a total of six straight-shaped resistors R_{E} are shown. In each row, the facing ends of a pair of adjacent straight-shaped resistors R_{E} are connected by via electrodes VE and a buried electrode BE.

In the example shown in FIG. 15C, all one ends of all straight-shaped resistors R_{E} in FIG. 15B are connected by via electrodes VE and a common buried electrode BE, and the other ends of all the straight-shaped resistors R_{E} are connected by via electrodes VE and a common buried electrode BE.

The vertical sectional configuration of the low resistance part (RPS, RNS) for detection can be the same as that of the high resistance part (RP, RN) except in plan shape. That is, the straight-shaped resistors R_{E}, the via electrodes VE, and the buried electrodes BE(buried wiring) described above are embedded within the insulating layer formed on the semiconductor substrate.

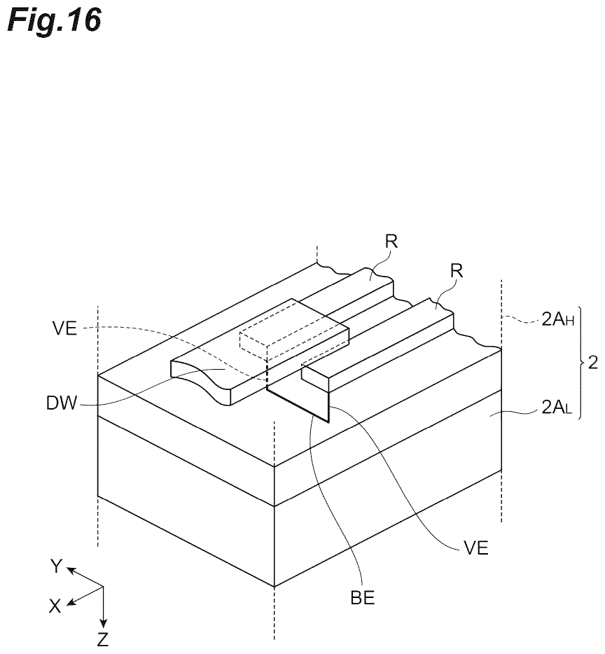

FIG. 16 is a perspective view in the vicinity of an end portion of a resistor layer.

A pair of resistors R is arranged adjacently. Each resistor R is connected on its underside, via the via electrode VE, to the top surface of the buried wiring BE. On the other hand, the top surface of the buried wiring BE is not connected to the lower surface of the dummy wiring DW, and a parasitic capacitor is formed between them. Such a resistor R(resistor layer) may be placed at a location away from the high potential side of the high resistance part. For example, in the third dummy wiring region DMY3 and the fourth dummy wiring region DMY4 in FIG. 11, this type of capacitor connection structure may be used. A direct connection structure employing the second via electrode VE2 is shown in FIG. 10.

Furthermore, it is possible that every connection structure between a resistor layer in the high resistance part and the dummy wiring is of the direct connection type. In particular, when forming a high resistance part within the insulating layer on a semiconductor substrate, it is possible to make the capacitance between the dummy wiring or the high resistance part and the semiconductor substrate extremely small. Therefore, everything can be directly connected without worrying about interactions with the capacitor connection structure. In other cases, for example, it is also possible to apply a mixture of the direct connection structure and the capacitor connection structure.

In the first high resistance part RP (or the second high resistance part RN), one can set the ratio of the number of capacitor connection structures to the number of direct connection structures as follows.

Let the direct connection structure be referred to as the first type, and the capacitor connection structure be referred to as the second type. The number of resistor layers (resistors R) that belong to the first type resistor layer group is N₁, the number of resistor layers (resistors R) that belong to the second type resistor layer group is N₂, and both N₁ and N₂ are natural numbers satisfying N₁<N₂. If a portion of the high-voltage side is provided with direct connection structures, the effect of preventing failure is achieved, and the remainder can be capacitor connection structures.

If the dummy wiring DW used in the capacitor connection structure is referred to as the third dummy wiring, the present device includes a third buried electrode BE capacitively coupled to the third dummy wiring, and a third resistor layer (resistor R) electrically connected to the third buried electrode BE.

The resistor chip's insulating layer contains a resistor that includes the first type resistor layer group and the second type resistor layer group. The first type resistor layer group (direct connection structure) is placed at a position closer to the longitudinal end (Y-axis direction) of the resistor (high resistance part RP or RN) than the second type resistor layer group (capacitor connection structure). The first type resistor layer group (direct connection structure) includes a plurality of first resistor units (the direct connection structure shown in FIG. 10) arranged in alignment. Each first resistor unit includes a first dummy wiring (the dummy wiring DW in FIG. 10), a first buried electrode (the buried electrode BE(N) or BE in FIG. 10) electrically connected to the first dummy wiring (the dummy wiring DW in FIG. 10), and a first resistor layer (resistor R) electrically connected to the first buried electrode. The second type resistor layer group (capacitor connection structure) includes a plurality of second resistor units (the capacitor connection structure shown in FIG. 16) arranged in alignment. Each second resistor unit includes a second dummy wiring (the dummy wiring DW in FIG. 16), a second buried electrode (the buried electrode BE in FIG. 16) that is capacitively coupled to the second dummy wiring, and a second resistor layer (the resistor R in FIG. 16) electrically connected to the second buried electrode.

In this case, a plurality of the first dummy wirings (the dummy wiring DW in FIG. 10) is arranged so as to surround the first electrode E1 (or the second electrode E2) located at the end portion of the resistor (dummy wiring DW in the first dummy wiring region DMY1 and the second dummy wiring region DMY2 in FIG. 11). The second dummy wiring (the dummy wiring DW in FIG. 16, the dummy wiring DW in the third dummy wiring region DMY3 and the fourth dummy wiring region DMY4 in FIG. 11) extends so as not to surround the first electrode E1 (or the second electrode E2).

The materials of the various components are described as follows.

The semiconductor substrate 1 (see FIGS. 6A to 6C and FIGS. 9A to 9C) may be conductive. For example, the impurity concentration of the semiconductor substrate 1 can be 5×10¹³ (cm⁻³) to 5×10¹⁴ (cm⁻³). The thickness of the semiconductor substrate 1 may be between 50 μm and 800 μm. Although silicon can be used as the material for the semiconductor substrate 1, a compound semiconductor such as SiC or SiGe is also possible.

The material of the resistor layer (straight-shaped resistor) constituting the resistor R has a higher resistivity than polysilicon. Specifically, the resistor (resistor layer) material includes chromium (Cr) and silicon (Si), and is CrSi, CrSiC, or CrSiN. Other materials can also be used. In other words, the resistor layer that constitutes the resistor can specifically include at least one metal compound selected from CrSi, CrSiN, CrSiO, TaN, and TiN. The resistor layer constituting the resistor can be formed by a sputtering method using a target containing the resistor material. Depending on the type of material used for the resistor R, a plating method can also be employed. The material of the resistor R may be composed of a single resistor material or a combination of multiple resistor materials. The thickness Rd of each resistor layer that constitutes the resistor R can be set between 1 nm and 5 nm. If the thickness Rd does not exceed the upper limit, a sufficiently high resistance can be achieved, and if it is at least the lower limit, adequate durability and strength of the resistor layer can be maintained.

Metal materials such as aluminum or copper may be used for the first electrode E1, the second electrode E2, and the buried electrodes (buried wiring). Refractory metals like tungsten (W) can be used for the various via electrodes, although other electrode materials are also possible.

(Supplementary Note) As described above, various exemplary embodiments within the present disclosure may be specified as the following supplementaries:

[A1] A semiconductor device comprising: an insulating layer formed on a semiconductor substrate 1; and a resistor (the first high resistance part RP, the second high resistance part RN, the first low resistance part RPS, the second low resistance part RNS) embedded in the insulating layer 2, wherein the resistor includes: a first resistor layer (resistor R(1) in FIG. 5); a first buried electrode (the second connection region BE(2) in FIG. 5) electrically connected to one end of the first resistor layer; a first dummy wiring (DW) capacitively coupled to the first buried electrode; a second resistor layer (resistor R(2) in FIG. 5) disposed adjacent to the first resistor layer (resistor R(1)); and a second buried electrode (BE(N)) electrically connected to one end of the second resistor layer (resistor R(2)) and electrically connected to the first dummy wiring (DW).

If one end of the first resistor layer (resistor R(1)) is at a high potential, failures may occur due to the potential difference with the adjacent second resistor layer (resistor R(2)). Therefore, the first resistor layer (resistor R(1)) is coupled to the second resistor layer (resistor R(2)) through the first buried electrode (the second connection region BE(2)), the parasitic capacitors (C1, C3, C11, C311), the first dummy wiring (DW, DW(1)), the second via electrode VE2, the second buried electrode (BE(N)), and so on. Because any AC voltage (surge voltage) applied to the first resistor layer is transmitted to the second resistor layer through the parasitic capacitors, the potential difference between the first resistor layer and the second resistor layer is relaxed at high speed, suppressing breakage. Note that the impedance of the parasitic capacitors decreases at high frequencies of the input signal.

[A2] A semiconductor device comprising: an insulating layer 2 formed on a semiconductor substrate 1; and a resistor (the first high resistance part RP, the second high resistance part RN, the first low resistance part RPS, the second low resistance part RNS) embedded in the insulating layer 2, wherein the resistor includes: a first resistor layer (resistor R(3) in FIG. 8); a first buried electrode (the buried electrode BE(N)) electrically connected to one end of the first resistor layer (resistor R(3)); a first dummy wiring (DW(1) in FIG. 8) electrically connected to the first buried electrode (the buried electrode BE(N)); a second dummy wiring (DW(2) in FIG. 8) capacitively coupled to the first dummy wiring (DW(1)); a second buried electrode (the buried electrode BE) electrically connected to the second dummy wiring (DW(2)); and a second resistor layer (resistor R(4) in FIG. 8) disposed adjacent to the first resistor layer (resistor R(3)) and electrically connected to the second buried electrode (the buried electrode BE).

When one end of resistor R(3) is at a high potential, a potential difference with its neighboring resistor R(4) may cause failures. Therefore, the resistor R(3) is coupled to the resistor R(4) via a parasitic capacitor between the dummy wirings. Any AC voltage (surge voltage) applied to resistor R(3) is transmitted to resistor R(4) through the parasitic capacitors, so the potential difference between resistor R(3) and resistor R(4) is quickly mitigated, preventing breakage.

[A3] The semiconductor device according to [A2], wherein the resistor includes: a third dummy wiring (the dummy wiring DW in FIG. 16); a third buried electrode (the buried electrode BE in FIG. 16) capacitively coupled to the third dummy wiring; and a third resistor layer (the resistor R in FIG. 16) electrically connected to the second resistor layer (the resistor R(4) in FIG. 8) and the third buried electrode.

The third resistor layer, located at a position removed from the end portion (high voltage side) in the longitudinal direction of the resistor, is electrically connected to the second resistor layer on the high-voltage side. Since it is located in a low-voltage area, there is less concern about damage due to potential differences, and a capacitive coupling (capacitor connection structure) can be used.

[A4] A semiconductor device comprising: an insulating layer 2 formed on a semiconductor substrate 1; and a resistor embedded in the insulating layer 2, the resistor comprising a first type resistor layer group (the direct connection structure in FIG. 10) and a second type resistor layer group (the capacitor connection structure in FIG. 16), wherein: the first type resistor layer group is disposed closer to an end portion in a longitudinal direction (Y-axis) of the resistor (the high resistance parts (RP, RN)) than the second type resistor layer group; the first type resistor layer group comprises a plurality of first resistor units (the direct connection structure in FIG. 10) arranged in alignment, each of the first resistor units comprising: a first dummy wiring (the dummy wirings DW in FIG. 10), a first buried electrode (the buried electrodes BE(N) in FIG. 10) electrically connected to the first dummy wiring, and a first resistor layer (the resistor R in FIG. 10) electrically connected to the first buried electrode; and the second type resistor layer group comprises a plurality of second resistor units (the capacitor connection structure in FIG. 16) arranged in alignment, each of the second resistor units comprising: a second dummy wiring (the dummy wirings DW in FIG. 16), a second buried electrode (the buried electrode BE in FIG. 16) capacitively coupled to the second dummy wiring, and a second resistor layer (the resistor R in FIG. 16) electrically connected to the second buried electrode (the buried electrode BE in FIG. 16).

[A5] The semiconductor device according to [A4], wherein a plurality of the first dummy wirings (the dummy wiring DW in FIG. 10) is arranged so as to surround a first electrode E1 (or the second electrode E2) located at an end portion of the resistor (the high resistance parts (RP, RN)), and the second dummy wiring (the dummy wiring DW in FIG. 16) extends so as not to surround the first electrode E1 (or the second electrode E2).

[A6] The semiconductor device according to [A4], wherein the number of resistor layers belonging to the first type resistor layer group is N1, and the number of resistor layers belonging to the second type resistor layer group is N2, where N1 and N2 are natural numbers satisfying N1<N2.

[A7] The semiconductor device according to [A1], wherein: in plan view, the resistor includes an extending region located at an end portion in the longitudinal direction (Y-axis direction) of the resistor (the first high resistance part RP, the second high resistance part RN, the first low resistance part RPS, the second low resistance part RNS); the extending region includes one or more dummy resistor layers (the resistor R within the dummy resistor R(Dmy)) embedded in the insulating layer 2; and one end of the dummy resistor layer is connected to the first buried electrode (the second connection region BE(2)).

[A8] The semiconductor device according to [A2], wherein: in plan view, the resistor includes an extending region located at an end portion in the longitudinal direction (Y-axis direction) of the resistor (the first high resistance part RP, the second high resistance part RN, the first low resistance part RPS, the second low resistance part RNS); the extending region includes one or more dummy resistor layers (the resistor R within the dummy resistor R(Dmy)) embedded in the insulating layer 2; and one end of the dummy resistor layer is connected to a buried electrode (the second connection region BE(2)).

[A9] The semiconductor device according to [A7], wherein: in plan view, X1 denotes a shortest distance between the first buried electrode (the second connection region BE(2)) included in the extending region and the second buried electrode (BE(N)); in plan view, X2 denotes a shortest distance between the first buried electrode (the third connection region BE(3)) included in the extending region and the first dummy wiring (dummy wiring DW on the high voltage side), and X1 and X2 satisfy X1≤X2.

[A10] The semiconductor device according to [A8], wherein: in plan view, the buried electrode (the second connection region BE(2)) included in the extending region is adjacent to the first buried electrode (the buried electrode BE(N)); in plan view, X1 denotes a shortest distance between the buried electrode included in the extending region and the first buried electrode;
in plan view, X2 denotes a shortest distance between the buried electrode included in the extending region and the first dummy wiring; and X1 and X2 satisfy X1≤X2.

[A11] A semiconductor device comprising a resistor provided on a semiconductor substrate, wherein: the resistor comprises: a first region comprising a first resistor layer group including a plurality of resistor layers (the resistor R(W) in the high resistance part (RP, RN) in FIG. 14), and a second region comprising a second resistor layer group including a plurality of resistor layers (the resistor R in the high resistance part (RP, RN) in FIG. 14); the first region (the formation region of resistor R(W)) is located closer to an end portion in a longitudinal direction Y-axis direction) of the resistor (the high resistance part) than the second region (the formation region of the resistor R); in the longitudinal direction of the resistor, ΔYRA denotes a shortest distance between the resistor layers (the resistor R(W)) belonging to the first resistor layer group, and ΔYRB denotes a shortest distance between the resistor layers (the resistor R in the high resistance part) belonging to the second resistor layer group; and ΔYRA and ΔYRB satisfy ΔYRB<ΔYRA.

It is to be understood that not all aspects, advantages and features described herein may necessarily be achieved by, or included in, any one particular example. Indeed, having described and illustrated various examples herein, it should be apparent that other examples may be modified in arrangement and detail.

### REFERENCE SIGNS LIST

1: semiconductor substrate
2: insulating layer
10: resistor chip
20: amplifier chip
C10: resistor circuit
C20: voltage detection circuit
BE, BE(N): buried electrode (buried wiring)
BE(1): first connection region
BE(2): second connection region
BE(3): third connection region
1R: annular conductor
2A: first dielectric layer
2B: second dielectric layer
2A_{H}: upper dielectric layer
2A_{L}: lower dielectric layer
4: protective film
4A: first protective film
4B: second protective film
4C: third protective film
10a: first inner lead
10b: second inner lead
10c: third inner lead
10d: fourth inner lead
10e: fifth inner lead
10f: sixth inner lead
10g: seventh inner lead
10h: eighth inner lead
10i: ninth inner lead
10A: first side
10B: second side
10C: third side
10D: fourth side
30: case
100: semiconductor package
110: first die pad
120: second die pad
200: battery
A1: first arrow
A2: second arrow
A3: third arrow
A4: fourth arrow
C1: first capacitor
C3: third capacitor
D1: recess
DMY1: first dummy wiring region
DMY2: second dummy wiring region
DMY3: third dummy wiring region
DMY4: fourth dummy wiring region
DW: dummy wiring
E1: first electrode
E2: second electrode
EG: reference electrode
EG1: first reference electrode
EG2: second reference electrode
EP: first output electrode
EN: second output electrode
GND: ground potential
HV(+): first input terminal
HV(−): second input terminal
INP: first input terminal
INN: second input terminal
N1: first node
N2: second node
N3: third node
Na, Nb, Nc, Nd, Ne, Nf, Ng, Nh: nodes
R, R(W): resistor
R: dummy resistor (Dmy)
R_{E}: straight-shaped resistor
RP: first high resistance part
RPS: first low resistance part
RN: second high resistance part
RNS: second low resistance part
RN1, RN2, RP1, RP2: high resistance parts
S: region
VC: reference terminal
Vcc: power supply voltage
VE: via electrode
VE2: second via electrode
Vout: output voltage
X1, X2: shortest distance
YD: gap
ΔYRA: first gap
ΔYRB: second gap

What is claimed is:

1. A semiconductor device comprising:
an insulating layer formed on a semiconductor substrate; and
a resistor embedded in the insulating layer;
wherein the resistor comprises:
a first resistor layer;
a first buried electrode electrically connected to one end of the first resistor layer;
a first dummy wiring capacitively coupled to the first buried electrode;
a second resistor layer disposed adjacent to the first resistor layer; and
a second buried electrode electrically connected to one end of the second resistor layer and electrically connected to the first dummy wiring.

2. A semiconductor device comprising:
an insulating layer formed on a semiconductor substrate; and
a resistor embedded in the insulating layer;
wherein the resistor comprises:
a first resistor layer;
a first buried electrode electrically connected to one end of the first resistor layer;
a first dummy wiring electrically connected to the first buried electrode;
a second dummy wiring capacitively coupled to the first dummy wiring;
a second buried electrode electrically connected to the second dummy wiring; and
a second resistor layer disposed adjacent to the first resistor layer and electrically connected to the second buried electrode.

3. The semiconductor device according to claim 2, wherein the resistor comprises:
a third dummy wiring;
a third buried electrode capacitively coupled to the third dummy wiring; and
a third resistor layer electrically connected to the second resistor layer and the third buried electrode.

4. A semiconductor device comprising:
an insulating layer formed on a semiconductor substrate; and
a resistor embedded in the insulating layer, the resistor comprising a first type resistor layer group and a second type resistor layer group, wherein:
the first type resistor layer group is disposed closer to an end portion in a longitudinal direction of the resistor than the second type resistor layer group;
the first type resistor layer group comprises a plurality of first resistor units arranged in alignment, each of the first resistor units comprising:
a first dummy wiring,
a first buried electrode electrically connected to the first dummy wiring, and
a first resistor layer electrically connected to the first buried electrode; and
the second type resistor layer group comprises a plurality of second resistor units arranged in alignment, each of the second resistor units comprising:
a second dummy wiring,
a second buried electrode capacitively coupled to the second dummy wiring, and
a second resistor layer electrically connected to the second buried electrode.

5. The semiconductor device according to claim 4,
wherein a plurality of the first dummy wirings is arranged so as to surround a first electrode located at an end portion of the resistor, and
wherein the second dummy wiring extends so as not to surround the first electrode.

6. The semiconductor device according to claim 4,
wherein a number of resistor layers belonging to the first type resistor layer group is N₁; and
wherein a number of resistor layers belonging to the second type resistor layer group is N₂,
where N₁ and N₂ are natural numbers satisfying N₁<N₂.

7. The semiconductor device according to claim 1,
wherein the resistor includes an extending region located at an end portion in a longitudinal direction of the resistor, in plan view;
wherein the extending region comprises one or more dummy resistor layers embedded in the insulating layer; and
wherein one end of the dummy resistor layer is connected to the first buried electrode.

8. The semiconductor device according to claim 2,
wherein the resistor includes an extending region located at an end portion in a longitudinal direction of the resistor, in plan view;
wherein the extending region comprises one or more dummy resistor layers embedded in the insulating layer; and
wherein one end of the dummy resistor layer is connected to a buried electrode.

9. The semiconductor device according to claim 7,
wherein X1 denotes a shortest distance between the first buried electrode included in the extending region and the second buried electrode, in plan view;
wherein X2 denotes a shortest distance between the first buried electrode included in the extending region and the first dummy wiring, in plan view, and
X1 and X2 satisfy X1≤X2.

10. The semiconductor device according to claim 8,
wherein the buried electrode included in the extending region is adjacent to the first buried electrode, in plan view;
wherein X1 denotes a shortest distance between the buried electrode included in the extending region and the first buried electrode, in plan view;
wherein X2 denotes a shortest distance between the buried electrode included in the extending region and the first dummy wiring, in plan view; and
X1 and X2 satisfy X1≤X2.
